(19) United States
(12) Patent Application Publication
(10) Pub. No.: US 2009/0166859 A1
(43) Pub. Date: Jul. 2, 2009

(54) Semiconductor device and method of manufacturing the same

(75) Inventors: Jingli Yuan, Gyeonggi-do (KR); Young Do Kweon, Seoul (KR); Jong Hwan Baek, Seoul (KR); Joon Seok Kang, Gyeonggi-do (KR); Seung Wook Park, Gyeonggi-do (KR); Jong Yun Lee, Incheon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/078,049

(22) Filed: Mar. 26, 2008

(30) Foreign Application Priority Data
Dec. 27, 2007 (KR) 10-2007-0139081

(51) Int. Cl. H01L 23/488; H01L 21/44

(52) U.S. Cl. 257/737; 438/614; 257/E23.023; 257/E21.476

(57) ABSTRACT

Provided is a semiconductor device including a wafer having an electrode pad; an insulating layer that is formed on the wafer and has an exposure hole formed in one side thereof, the exposure layer exposing the electrode pad, and a support post formed in the other side, the support post having a buffer groove; a redistribution layer that is formed on the top surface of the insulating layer and has one end connected to the electrode pad and the other end extending to the support post; an encapsulation layer that is formed on the redistribution layer and the insulating layer and exposes the redistribution layer formed on the support post; and a solder bump that is provided on the exposed portion of the redistribution layer.

### CROSS-REFERENCE TO RELATED APPLICATIONS

This application claims the benefit of Korean Patent Application No. 10-2007-0139081 filed with the Korea Intellectual Property Office on Dec. 27, 2007, the disclosure of which is incorporated herein by reference.

### BACKGROUND OF THE INVENTION

1. Field of the Invention

The present invention relates to a semiconductor device and a method of manufacturing the same, which can minimize the damage of solder bumps to enhance reliability.

2. Description of the Related Art

Recently, as demand for miniaturization of electronic apparatuses and devices is increasing, the miniaturization and high integration of semiconductor devices used therein is required.

Accordingly, chip-size-package (CSP) semiconductor devices, of which the size is reduced by making the shape of semiconductor devices similar to that of each semiconductor element (semiconductor chip), are being developed and manufactured.

Hereinafter, a conventional semiconductor device will be described in detail with reference to accompanying drawings.

FIG. 1 is a cross-sectional view of a conventional semiconductor device. As shown in FIG. 1, the conventional semiconductor device includes a wafer 1 having an electrode pad 2 formed thereon, an insulating layer 3 which is formed on the top surface of the wafer 1 and exposes the electrode pad 2, a redistribution layer 4 which is formed on the top surface of the insulating layer 3 and has one end connected to the electrode pad 2, a resin layer 5 which is formed on the insulating layer 3 and the redistribution layer 4 and exposes the other end of the redistribution layer 4, a bonding assist layer 6 which is formed on the top surface of the resin layer 5 and is connected to the other end of the redistribution layer 4, and a solder ball 7 which is formed on the bonding assist layer 6.

Further, a method of manufacturing such a conventional semiconductor device is performed as follows.

First, the electrode pad 2 is formed on the wafer 1, and the insulating layer 3 is applied onto the top surface of the wafer 1.

The insulating layer 3 is etched through a photolithography process such that the electrode pad 2 is exposed.

Then, a metal layer is applied on the insulating layer 3 through a vacuum deposition process, and is then etched through the photolithography process to thereby form a redistribution layer 4 which is used as a metal pattern connected to the electrode pad 2 exposed through the insulating layer 3.

Further, a resin layer 5 is applied on the insulating layer 3 and the redistribution layer 4, and is then etched through the photolithography process such that part of the redistribution layer 4 in the opposite side to a side connected to the electrode pad 2 is exposed.

Next, a metal layer is applied on the resin layer 5 through the vacuum deposition process, and is then etched through the photolithography process to thereby form a bonding assist layer 6 which is connected to the exposed portion of the redistribution layer 4 and is used as a bonding portion on which a solder ball 7 is formed.

Finally, the solder ball 7 is formed on the bonding assist layer 6 through a reflow process.

However, the conventional semiconductor device has the following problems.

When the conventional semiconductor device is mounted on a printed circuit board, stress is concentrated on the solder ball 7 due to a difference in thermal expansion coefficient between the printed circuit board and the semiconductor device. Then, a crack may occur in the solder ball 7, or the solder ball 7 may be damaged.

That is, while the thermal expansion coefficient of typical semiconductor devices is about 3 ppm/k, the thermal expansion coefficient of the printed circuit board is about 20 ppm/k, which means that a difference in thermal expansion coefficient is large. Therefore, after the semiconductor device is mounted on the printed circuit board, the semiconductor device or printed circuit board is significantly bent due to the difference in thermal expansion coefficient. Accordingly, stress is concentrated on the solder ball 7 serving as a medium through which the semiconductor device is mounted on the printed circuit board. As a result, a crack occurs in the solder ball 7, or the solder ball 7 is damaged, thereby degrading reliability.

Further, the manufacturing process of the conventional semiconductor device is complicated and takes a long time. Therefore, a manufacturing cost increases, and productivity is reduced.

That is, the etching process, in which the resin layer 5 is etched through the photolithography process to expose the redistribution layer 4 and the metal layer is etched through the photolithography process to form the bonding assist layer 6, should be performed in addition to the etching process in which the insulating layer 3 is etched through the photolithography process to expose the electrode pad 2 and the metal layer is etched through the photolithography process to form the redistribution layer 4. Therefore, the manufacturing process is complicated and takes a long time. As a result, a manufacturing cost increases, and productivity is reduced.

### SUMMARY OF THE INVENTION

An advantage of the present invention is that it provides a semiconductor device, of which the structure is improved to minimize the damage of solder bumps caused by a difference in thermal expansion coefficient, thereby enhancing the reliability, and a method of manufacturing the same, which can simplify a manufacturing process to reduce a manufacturing cost and to enhance productivity.

Additional aspects and advantages of the present general inventive concept will be set forth in part in the description which follows and, in part, will be obvious from the description, or may be learned by practice of the general inventive concept.

According to an aspect of the invention, a semiconductor device comprises a wafer having an electrode pad; an insulating layer that is formed on the wafer and has an exposure hole formed in one side thereof, the exposure layer exposing the electrode pad, and a support post formed in the other side, the support post having a buffer groove; a redistribution layer that is formed on the top surface of the insulating layer and has one end connected to the electrode pad and the other end extending to the support post; an encapsulation layer that is formed on the redistribution layer and the insulating layer and exposes the redistribution layer formed on the support post; and a solder bump that is provided on the exposed portion of the redistribution layer.

The buffer groove may be formed in such a shape that surrounds the circumference of the support post and may be formed from the top surface to the lower surface of the insulating layer.

The buffer groove may be formed by etching the insulating layer through a photolithography process.

According to another aspect of the invention, a method of manufacturing a semiconductor device comprises the steps of: forming an insulating layer on the top surface of a wafer having an electrode pad formed therein; forming an expose hole and a support post in the insulating layer, the exposure hole exposing the electrode pad, the support post having a buffer groove formed therearound; forming a redistribution layer on the insulting layer, the redistribution layer having one end connected to the electrode pad and the other end extending to the support post; forming an encapsulation layer on the redistribution layer and the insulating layer; forming a connection hole in the encapsulation layer, the connection hole exposing the redistribution layer formed on the support post; and forming a solder bump on the exposed portion of the redistribution layer.

The buffer groove may be formed in such a shape that surrounds the circumference of the support post and may be formed from the top surface to the lower surface of the insulating layer.

The buffer groove may be formed by etching the insulating layer through a photolithography process.

The connection hole is formed by etching the encapsulation layer through a photolithography process.

According to a further aspect of the invention, a semiconductor device comprises a wafer having an electrode pad; an insulating layer that is formed on the wafer and has an exposure hole formed in one side thereof, the exposure layer exposing the electrode pad, and a support post formed in the other side, the support post having a buffer groove; a redistribution layer that is formed on the top surface of the insulating layer and has one end connected to the electrode pad and the other end extending to the support post; a conductive post that is formed on the redistribution layer formed on the support post; an encapsulation layer that is formed on the redistribution layer and the insulating layer such that the upper end of the conductive post is exposed; and a solder bump that is formed on the exposed upper end of the conductive post.

The conductive post may be formed of conductive polymer and may be formed by stencil printing or screen printing.

The lower end of the solder bump may be formed to the inside of the upper end of the conductive post.

According to a still further aspect of the invention, a method of manufacturing a semiconductor device comprises the steps of: forming an insulating layer on the top surface of a wafer having an electrode pad formed therein; forming an expose hole and a support post in the insulating layer, the exposure hole exposing the electrode pad, the support post having a buffer groove formed therearound; forming a redistribution layer on the insulating layer, the redistribution layer having one end connected to the electrode pad and the other end extending to the support post; forming a conductive post on the redistribution layer formed on the support post; forming an encapsulation layer on the redistribution layer and the insulating layer such that the upper end of the conductive post is exposed; and forming a solder bump on the exposed upper end of the conductive post.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a conventional semiconductor device;

FIG. 2 is a cross-sectional view of a semiconductor device according to a first embodiment of the invention;

FIGS. 3 to 8 are process diagrams sequentially showing a method of manufacturing the semiconductor device according to the first embodiment of the invention; and

FIG. 9 is a cross-sectional view of a semiconductor device according to a second embodiment of the invention.

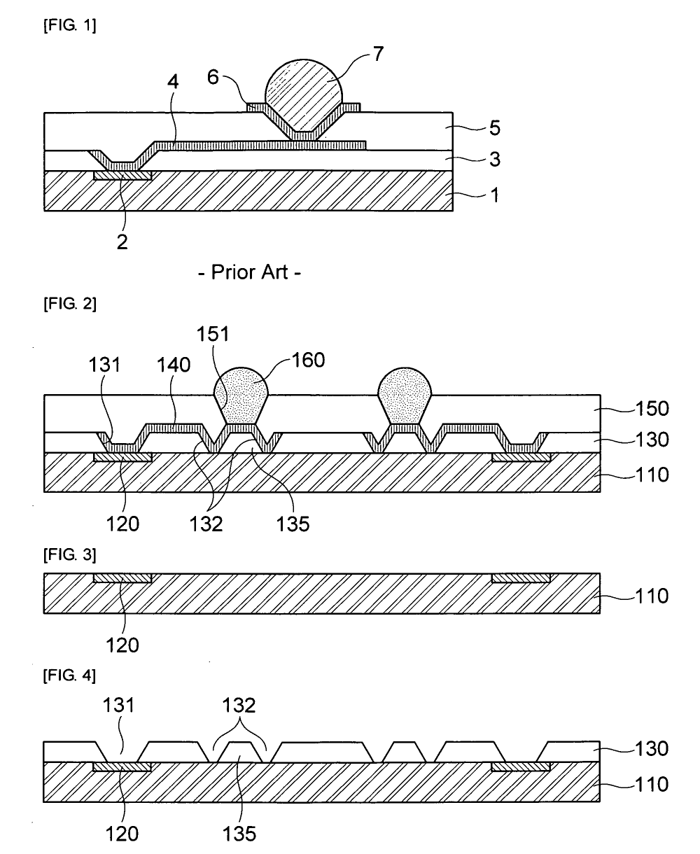

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures.

Hereinafter, a semiconductor device and a method of manufacturing the same according to the present invention will be described in detail with reference to the accompanying drawings.

Semiconductor device according to first embodiment

Referring to FIG. 2, a semiconductor device according to a first embodiment of the invention will be described.

FIG. 2 is a cross-sectional view of a semiconductor device according to a first embodiment of the invention.

As shown in FIG. 2, the semiconductor device according to the first embodiment of the invention includes a wafer 110 having an electrode pad 120; an insulating layer 130 which is formed on the top surface of the wafer 110 and in which an exposure hole 131 exposing the electrode pad 120 is formed in one side of the insulating layer 130 and a support post 135 having a buffer groove 132 is formed in the other side thereof; a redistribution layer 140 which is formed on the top surface of the insulating layer 130 and of which one end is connected to the electrode pad 120 and the other end extends to the support post 135; an encapsulation layer 150 which is formed on the redistribution layer 140 and the insulating layer 130 and exposes the redistribution layer 140 formed on the support post 135; and a solder bump 160 provided on the exposed portion of the redistribution layer 140.

Preferably, the exposure hole 131 and the buffer groove 132 formed in the insulating layer 130 are formed by etching the insulating layer 130 through a photolithography process.

That is, as the buffer groove 132 is formed, the support post 135 is also formed.

At this time, the buffer groove 132 is formed in such a shape that surrounds the circumference of the support post 135.

When the insulating layer 130 is etched by using a normal photo mask with a black and clear pattern as an etching mask, the buffer groove 132 may be formed in a hole shape which extends from the top surface to the lower surface of the insulating layer 130, like the exposure hole 131.

Further, when the insulating layer 130 is etched by using a half-tone mask or gray-scale mask as an etching mask, the buffer groove 132 may be formed in a groove shape such that the insulating layer 130 is partially etched from the top surface to the inside thereof, although not shown.

In the above-described semiconductor device according to the first embodiment of the invention, the solder bump 160 is formed on the redistribution layer 140 formed on the support post 135 having the buffer groove 131 formed therearound. Then, stress concentrated to the solder bump 170 is distributed, buffered, and relieved through the buffer groove 131 as much as possible. Therefore, it is possible to minimize a crack or damage of the solder bump 170, thereby enhancing the reliability of the semiconductor device.

### Method of Manufacturing Semiconductor Device According to First Embodiment

Referring to FIGS. 3 to 8, a method of manufacturing the semiconductor device according to the first embodiment of the invention will be described.

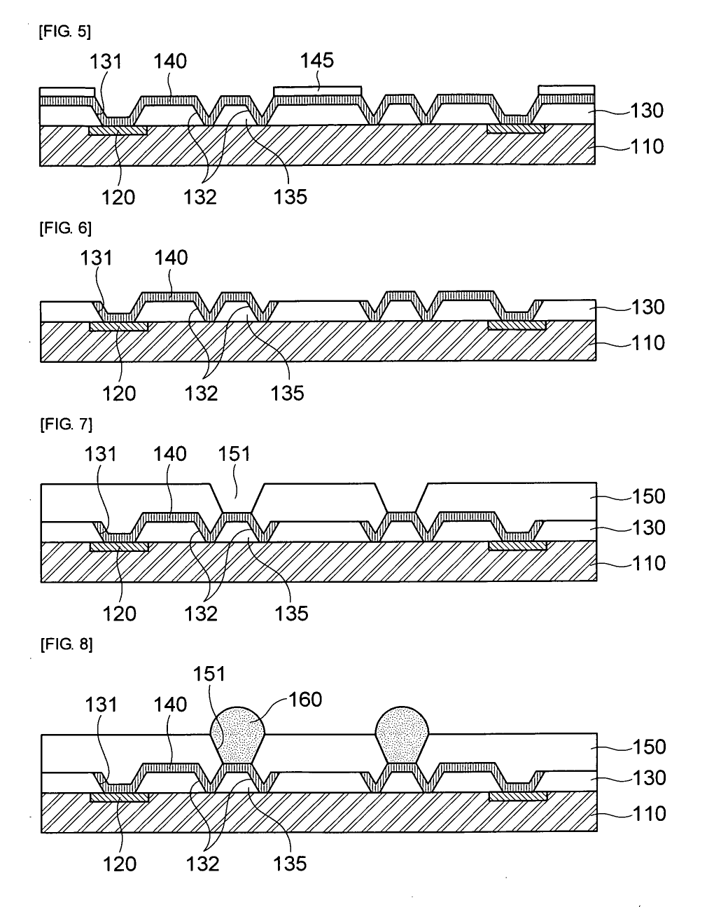

FIGS. 3 to 8 are process diagrams sequentially showing a method of manufacturing the semiconductor device according to the first embodiment of the invention. FIG. 3 shows a state where an electrode pad is formed on the top surface of a wafer. FIG. 4 shows a state where an exposure hole and a support post having a buffer groove are formed in an insulating layer. FIG. 5 shows a state where a mask is patterned on the top surface of a metal layer. FIG. 6 shows a state where a redistribution layer is formed. FIG. 7 shows a state where a connection hole is formed in an encapsulation layer. FIG. 8 shows a state where a solder bump is formed.

First, as shown in FIG. 3, an electrode pad 120 is formed on the top surface of a wafer 110.

Then, as shown in FIG. 4, an insulating layer 130 is applied on the top surface of the wafer 110 and is then etched through a photolithography process to form a buffer groove 132 and an exposure hole 131 which exposes the electrode pad 120.

As the buffer groove 132 is formed, the support post 135 is formed inside the buffer groove 132.

When the insulating layer 130 is etched by using a normal photo mask with a black and clear pattern as an etching mask, the buffer groove 132 may be formed in a hole shape which extends from the top surface to the lower surface of the insulating layer 130, like the exposure hole 131.

Further, when the insulating layer 130 is etched by using a half-tone mask or gray-scale mask as an etching mask, the buffer groove 132 may be formed in a groove shape such that the insulating layer 130 is partially etched from the top surface thereof to the inside thereof.

Then, as shown in FIG. 5, a metal layer is applied on the top surface of the insulating layer 130, and an etching mask 145 is patterned on the metal layer to etch the metal layer through the photolithography process.

After the photolithography process, a redistribution layer 140 is formed, which has one end connected to the electrode pad 120 and the other end extending to the support post 135, as shown in FIG. 6.

The redistribution layer 140 is used as a metal pattern connected to the electrode pad 120 exposed through the exposure hole 131 of the insulating layer 130.

Then, as shown in FIG. 7, an encapsulation layer 150 having a connection hole 151 is formed on the redistribution layer 140 and the insulating layer 130.

At this time, the connection hole 151 may be formed by the following process. First, epoxy resin or the like is applied onto the redistribution layer 140 and the insulating layer 130 to form an epoxy resin layer. Then, the epoxy resin layer is etched through the photolithography process to form the connection hole 151.

Finally, the solder bump 160 is formed in the connection hole 155 of the encapsulation layer 150 through a reflow process or the like. Then, the semiconductor device according to the first embodiment of the invention is completed.

At this time, the solder bump 160 is bonded to the redistribution layer 140 exposed through the connection hole 151 such that they are electrically connected to each other. Therefore, when the semiconductor device is mounted on an external substrate, the semiconductor device can be used as an external terminal.

### Semiconductor Device According to Second Embodiment

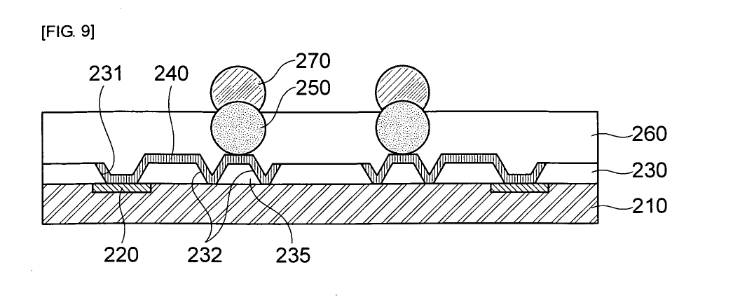

Referring to FIG. 9, a semiconductor device according to a second embodiment of the invention will be described.

FIG. 9 is a cross-sectional view of a semiconductor device according to a second embodiment of the invention.

As shown in FIG. 9, the semiconductor device according to the second embodiment of the invention includes a wafer 210 having an electrode pad 220; an insulating layer 230 which is formed on the top surface of the wafer 210 and in which an exposure hole 231 exposing the electrode pad 220 is formed in one side of the insulating layer 230 and a support post 235 having a buffer groove 232 is formed in the other side thereof; a redistribution layer 240 which is formed on the top surface of the insulating layer 230 and of which one end is connected to the electrode pad 220 and the other end extends to the support post 235; a conductive post 250 formed on the redistribution layer 240 formed on the support post 235; an encapsulation layer 260 which is formed on the redistribution layer 240 and the insulating layer 230 and exposes the upper end of the conductive post 250; and a solder bump 270 provided on the exposed upper end of the conductive post 250.

The conductive post 250 may be composed of a conductive polymer post.

Preferably; the conductive post 250 is formed through a printing method such as stencil printing or screen printing.

That is, as the conductive post 250 is formed on the redistribution layer 240 formed on the support post 235 by the stencil printing or screen printing, it is possible to omit the photolithography process for a space in which the bonding assist layer for connecting the redistribution layer and the solder ball is to be formed and the photolithography process for forming the bonding assist layer in the related art. Therefore, the manufacturing process is simplified, and the manufacturing time is reduced, which makes it possible to reduce a manufacturing cost and to enhance productivity.

Further, the conductive post 250 is formed of conductive polymer, is surrounded by the encapsulation layer 260 except for the upper end thereof to which the solder bump 270 is bonded, and is formed on the redistribution layer 240 formed on the support post 235 having the buffer groove 232 therearound. Further, the conductive post 250 serves to distribute and buffer stress concentrated on the solder bump 270 as much as possible. Therefore, it is possible to minimize a crack or damage of the solder bump 270, thereby enhancing the reliability of the semiconductor device.

The lower end of the solder bump 270 may be formed to the inside of the upper end of the conductive post 250.

Therefore, the bonding property of the solder bump 270 is enhanced, thereby minimizing a crack or damage of the solder bump 270 caused by an external force. As a result, it is possible to enhance the reliability of the semiconductor device.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A semiconductor device comprising:
a wafer having an electrode pad;
an insulating layer that is formed on the wafer and has an exposure hole formed in one side thereof, the exposure layer exposing the electrode pad, and a support post formed in the other side, the support post having a buffer groove;
a redistribution layer that is formed on the top surface of the insulating layer and has one end connected to the electrode pad and the other end extending to the support post;
an encapsulation layer that is formed on the redistribution layer and the insulating layer and exposes the redistribution layer formed on the support post; and
a solder bump that is provided on the exposed portion of the redistribution layer.

2. The semiconductor device according to claim 1, wherein the buffer groove is formed in such a shape that surrounds the circumference of the support post.

3. The semiconductor device according to claim 1, wherein the buffer groove is formed from the top surface to the lower surface of the insulating layer.

4. The semiconductor device according to claim 1, wherein the buffer groove is formed by etching the insulating layer through a photolithography process.

5. A method of manufacturing a semiconductor device, comprising the steps of:
forming an insulating layer on the top surface of a wafer having an electrode pad formed therein;
forming an expose hole and a support post in the insulating layer, the exposure hole exposing the electrode pad, the support post having a buffer groove formed therearound;
forming a redistribution layer on the insulting layer, the redistribution layer having one end connected to the electrode pad and the other end extending to the support post;
forming an encapsulation layer on the redistribution layer and the insulating layer;
forming a connection hole in the encapsulation layer, the connection hole exposing the redistribution layer formed on the support post; and
forming a solder bump on the exposed portion of the redistribution layer.

6. The method according to claim 5, wherein the buffer groove is formed in such a shape that surrounds the circumference of the support post.

7. The method according to claim 5, wherein the buffer groove is formed from the top surface to the lower surface of the insulating layer.

8. The method according to claim 5, wherein the buffer groove is formed by etching the insulating layer through a photolithography process.

9. The method according to claim 5, wherein the connection hole is formed by etching the encapsulation layer through a photolithography process.

10. A semiconductor device comprising:
a wafer having an electrode pad;
an insulating layer that is formed on the wafer and has an exposure hole formed in one side thereof, the exposure layer exposing the electrode pad, and a support post formed in the other side, the support post having a buffer groove;
a redistribution layer that is formed on the top surface of the insulating layer and has one end connected to the electrode pad and the other end extending to the support post;
a conductive post that is formed on the redistribution layer formed on the support post;
an encapsulation layer that is formed on the redistribution layer and the insulating layer such that the upper end of the conductive post is exposed; and
a solder bump that is formed on the exposed upper end of the conductive post.

11. The semiconductor device according to claim 10, wherein the conductive post is formed of conductive polymer.

12. The semiconductor device according to claim 10, wherein the conductive post is formed by stencil printing or screen printing.

13. The semiconductor device according to claim 10, wherein the lower end of the solder bump is formed to the inside of the upper end of the conductive post.

14. A method of manufacturing a semiconductor device, comprising the steps of:
forming an insulating layer on the top surface of a wafer having an electrode pad formed therein;
forming an expose hole and a support post in the insulating layer, the exposure hole exposing the electrode pad, the support post having a buffer groove formed therearound;
forming a redistribution layer on the insulating layer, the redistribution layer having one end connected to the electrode pad and the other end extending to the support post;
forming a conductive post on the redistribution layer formed on the support post;
forming an encapsulation layer on the redistribution layer and the insulating layer such that the upper end of the conductive post is exposed; and
forming a solder bump on the exposed upper end of the conductive post.
